(19) United States
(12) Patent Application Publication
(10) Pub. No.: US 2025/0056722 A1
(43) Pub. Date: Feb. 13, 2025

(54) HIGH-INTEGRATION-LEVEL CARRIER PLATE AND MANUFACTURING METHOD

(71) Applicant: SHANGHAI METAPWR ELECTRONICS CO., LTD, Shanghai (CN)

(72) Inventors: Shouyu Hong, Shanghai (CN); Xiaoni Xin, Shanghai (CN)

(73) Assignee: SHANGHAI METAPWR ELECTRONICS CO., LTD, Shanghai (CN)

(21) Appl. No.: 18/796,184

(22) Filed: Aug. 6, 2024

(30) Foreign Application Priority Data
Aug. 8, 2023 (CN) 202310988472.1

(51) Int. Cl. H05K 1/09; H05K 1/18; H05K 3/46

(52) U.S. Cl. CPC H05K 1/09; H05K 1/181; H05K 3/4644

(57) ABSTRACT

A high-integration carrier plate and a manufacturing method thereof are disclosed. The carrier plate is configured for a power supply module, the carrier plate includes at least one hollowed-out area, an inductance element is arranged in the hollowed-out area, the inductance element comprises a magnetic core and a winding penetrating through the magnetic core, at least one part of a side wall of the hollowed-out area is provided with a side wall metal piece, the at least one side wall metal piece is used for being electrically connected with one electrostatic potential end of the power supply module, and the inductance element is fixedly connected with the side wall of the hollowed-out area through an insulating bonding medium layer.

### CROSS-REFERENCE TO RELATED APPLICATION

This application claims the priority benefit of China patent application serial no. 202310988472.1 filed on Aug. 8, 2023. The entirety of the above-mentioned patent application is hereby incorporated by reference herein and made a part of this specification.

### BACKGROUND

### Technical Field

The present application belongs to the field of high-frequency power supplies, and particularly relates to a high-integration level carrier plate and manufacturing method.

### Description of Related Art

Along with increasingly vigorous requirements of various artificial intelligence, data processing and the like, global computing power energy consumption presents explosive growth. Moreover, due to the fact that the power consumption of the computing power units is larger and larger, the size limitation is more and more harsh, and higher and higher requirements are provided for the occupied area, the height, the efficiency, the heat dissipation, the electromagnetic interference and the like of the energy processing unit. A power supply for directly supplying power to a computing chip generally adopts a BUCK circuit as shown in FIG. 1 and comprises a magnetic element, a capacitor, a power chip and the like.

How to efficiently integrate these parts, simultaneously satisfying numerous requirements of the system on the energy processing unit, reducing the conduction impedance, reducing the module size, effectively reducing the loop inductance of the VIN-GND loop, and avoiding the interference of a jump point such as SW on an external signal, which is an urgent problem to be solved.

### SUMMARY

In view of the above, one of the objectives of the present application is to provide a high-integration carrier plate and a manufacturing method therefor. The inductor element is embedded into a printed circuit layer substrate, a smaller VIN-GND loop is achieved by using the wiring of the printed circuit layer substrate frame, and parasitic parameters are reduced.

In order to achieve the above purpose, the application discloses a high-integration carrier plate. The carrier plate is used for a power supply module and comprises at least one hollowed-out area, an inductance element is arranged in the hollowed-out area, the inductance element comprises a magnetic core and a winding penetrating through the magnetic core, a side wall metal piece is arranged on at least one part of the side wall of the hollowed-out area, the at least one side wall metal piece is used for being electrically connected with one electrostatic potential end of the power supply module, and the inductance element is fixedly connected with the side wall of the hollowed-out area through an insulating bonding medium layer.

Preferably, a first outer side metal piece corresponding to a position of the side wall metal piece is arranged on an outer side wall of at least one part of the carrier plate, and the first outer side metal piece and the corresponding side wall metal piece are respectively used for being electrically connected with terminals with different electrical properties of the power supply module.

Preferably, at least a part of the outer side wall of the carrier plate is provided with a second outer side metal piece corresponding to the position of the side wall metal piece, and the second outer side metal piece is electrically connected to the corresponding side wall metal piece.

Preferably, the second outer side metal piece and the at least one first outer side metal piece are arranged adjacent to each other;

the second outer side metal piece is electrically connected with the adjacent first outer side metal piece, or the side wall metal piece at the corresponding position of the second outer side metal piece is electrically connected with the side wall metal piece at the corresponding position of the adjacent first outer side metal piece.

Preferably, the side wall metal parts are arranged in an array in the horizontal direction of the carrier plate and are electrically and alternately arranged.

Preferably, a horizontal metal layer is arranged in an area between the first outer side metal piece and the side wall metal piece at a corresponding position, and each horizontal metal layer is electrically connected with the first outer side metal piece or the side wall metal piece at the corresponding position.

Preferably, a plurality of horizontal metal layers are arranged and are alternately electrically connected with the side wall metal pieces/the first outer side metal pieces.

Preferably, an insulating dielectric layer is further provided above or below the at least one horizontal metal layer.

Preferably, at least one part of the first outer side metal piece does not extend to at least one surface of the carrier plate in a thickness direction of the carrier plate.

Preferably, at least a part of the sidewall metal piece does not extend to at least one surface of the carrier plate along the thickness direction of the carrier plate.

Preferably, further comprising a signal electrical connector, the signal electrical connector is arranged in a through hole, and shielding of electromagnetic interference is achieved between the signal electrical connector and the winding through the side wall metal piece.

Preferably, at least one surface of the carrier plate is provided with a wiring layer.

Preferably, the wiring layer comprises an insulating dielectric region between wirings.

Preferably, at least one surface of the carrier plate is provided with a printed circuit board stack layer, the printed circuit board stack layer is fixedly connected with the carrier plate through an insulating bonding medium layer, and the printed circuit board stack layer is electrically connected with the carrier plate through a bonding material piece.

Preferably, the side walls of the carrier plate and the printed circuit board stack layer are provided with an integrated outer metal piece.

Preferably, at least one of the printed circuit board stack layers is provided with a laminated hollowed-out area, the laminated hollowed-out area is used for arranging a power supply circuit assembly, and the power supply circuit assembly comprises a capacitor.

The application discloses a manufacturing method, comprising the following steps:
S1, hollowing out a printed circuit layer substrate, and then carrying out whole-plate copper plating on the printed circuit layer substrate;
S2, plating a protective layer on the whole printed circuit layer substrate;
S3, graphic definition: removing a protective layer of a designated area, wherein the designated area comprises at least a part of an edge area, and the edge area is an edge of a printed circuit layer substrate and/or a side wall edge formed by hollowing;
S4, etching: removing copper in the designated area, and enabling the side wall copper plating of the edge area to be lower than an upper surface/a lower surface of the printed circuit layer substrate;
S5: removing the remaining protective layer to form a carrier plate frame; and
S6, laminating: fixedly connecting the inductance element and the carrier plate frame through an insulating bonding dielectric layer.

Preferably, a width of a horizontal section of the edge area is less than 200 μm, and a width of a vertical segment of the edge area is less than 200 μm.

Preferably, the width of the horizontal section of the edge area is smaller than 100 μm, and the width of the vertical section of the edge area is smaller than 100 μm.

Compared with the prior art, the application has the following beneficial effects:
(1) According to the application, the inductance element is embedded into the printed circuit layer substrate, a VIN-GND loop with a smaller loop area can be formed by utilizing the hollowed-out area inner wall, the outer side wall and the internal wiring structure of the printed circuit layer substrate, the parasitic inductance of the loop is greatly reduced, and loop parameters are optimized.
(2) According to the high-integration carrier plate and the optimized edge structure, the wiring difficulty of an external mainboard can be reduced, the wiring efficiency is improved, the wiring impedance is reduced, meanwhile, the overall height of the power supply module is reduced, and the efficiency is improved, and the loss is reduced.
(3) The wiring structure of the inner wall of the hollowed-out area of the printed circuit layer substrate provided by the application can provide thermal diffusion and improve heat dissipation in addition to increasing the through-flow and reducing the connection impedance.
(4) By means of the wiring structure of the inner wall, the outer side wall and the interior of the hollowed-out area of the printed circuit layer substrate, the diffusion rate of moisture into the substrate can be increased, and the reliability of the module in use is improved.

### BRIEF DESCRIPTION OF THE DRAWINGS

FIG. 1 is a schematic diagram of a Buck circuit in the prior art;

FIG. 2A to FIG. 2D and FIG. 3A to FIG. 3D are schematic diagrams of a first embodiment of the present application;

FIG. 4A to FIG. 4C are schematic diagrams of a second embodiment of the present application;

FIG. 5A to FIG. 5D are schematic diagrams of a third embodiment of the present application;

FIG. 6A to FIG. 6G are schematic diagrams of a fourth embodiment of the present application;

FIG. 7A to FIG. 7E and FIG. 8A to FIG. 8B are schematic diagrams of a fifth embodiment of the present application;

FIG. 9A, FIG. 9B, FIG. 10A, FIG. 10B and FIG. 11 are schematic diagrams of a sixth embodiment of the present application;

FIG. 12A to FIG. 12F and FIG. 13A to FIG. 13C are schematic diagrams of a seventh embodiment of the present application;

FIG. 14A to FIG. 14D are schematic diagrams of eighth Embodiment of the present application.

### DESCRIPTION OF THE EMBODIMENTS

The present application discloses various embodiments or examples of implementing the thematic technological schemes mentioned. To simplify the disclosure, specific instances of each element and arrangement are described below. However, these are merely examples and do not limit the scope of protection of this application. For instance, a first feature recorded subsequently in the specification formed above or on top of a second feature may include an embodiment where the first and second features are formed through direct contact, or it may include an embodiment where additional features are formed between the first and second features, allowing the first and second features not to be directly connected. Additionally, these disclosures may repeat reference numerals and/or letters in different examples. This repetition is for brevity and clarity and does not imply a relationship between the discussed embodiments and/or structures. Furthermore, when a first element is described as being connected or combined with a second element, this includes embodiments where the first and second elements are directly connected or combined with each other, as well as embodiments where one or more intervening elements are introduced to indirectly connect or combine the first and second elements.

One of the cores of the present application is to provide a high-integration carrier plate and a manufacturing method therefor. An inductance element is embedded into a printed circuit layer substrate, a smaller VIN-GND loop is achieved by means of the wiring of the printed circuit layer substrate frame, and parasitic parameters are reduced.

### Embodiment 1

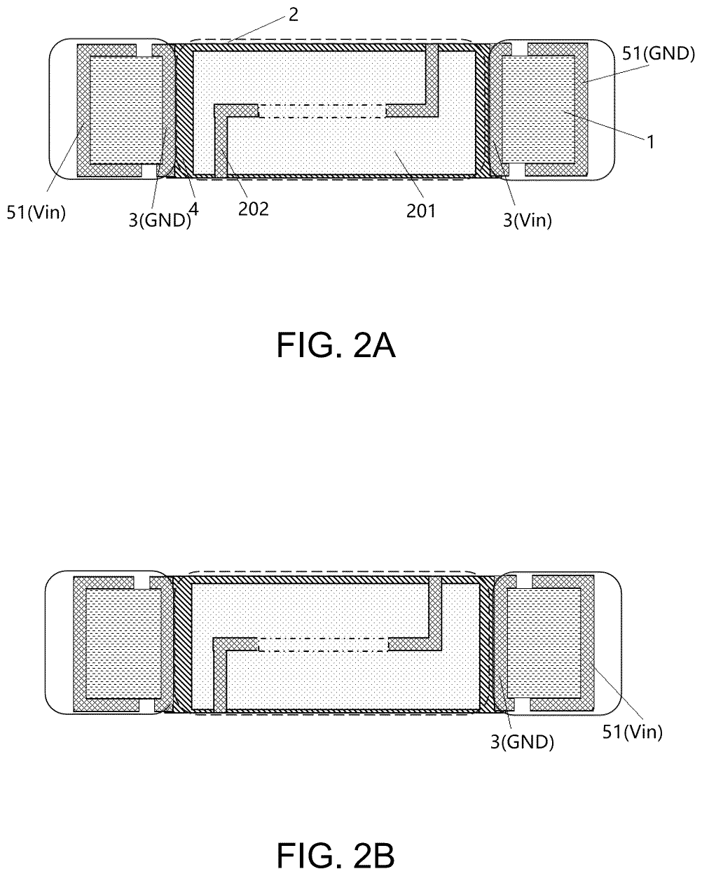

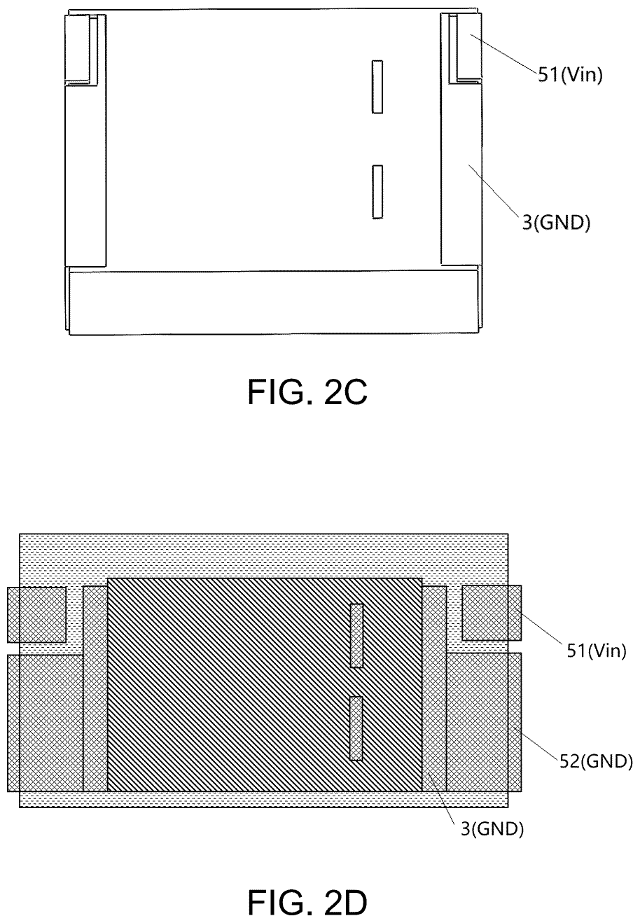

The high-integration carrier plate disclosed by the embodiment is mainly used in the power supply module, as shown in FIG. 2A to FIG. 2C, the carrier plate comprises a printed circuit layer substrate 1 and at least one hollowed-out area, and an inductance element 2 is arranged in the hollowed-out area, and the inductance element 2 comprises a magnetic core 201 and a winding 202 penetrating through the magnetic core, and the first end of the winding 202 is fan-out from the surface of the first surface of the carrier plate, and a second end of the winding 202 is fan-out from the second surface of the carrier plate; at least one side wall of the hollowed-out area is provided with a side wall metal piece 3; the at least one side wall metal piece 3 is used for being electrically connected with one electrostatic potential end of the power supply module (such as a Vin end and a GND end); and the inductance element 2 is fixedly connected with the side wall of the hollowed-out area through an insulating bonding medium layer 4.

A first outer side metal piece 51 corresponding to the position of the side wall metal piece 3 is arranged on the side wall of the outer side of at least one part of the printed circuit layer substrate 1, the first outer side metal piece 51 and the corresponding side wall metal piece 3 are respectively used for being electrically connected with terminals with different electrical properties of the power supply module, as shown in FIG. 2A, one part of the side wall metal pieces 3 are GND electric connector, the other part is divided into VIN electric connector, and the first outer side metal pieces 51 are opposite to the corresponding side wall metal pieces 3. In FIG. 2B and FIG. 2C (the perspective view of FIG. 2B), the side wall metal pieces 3 are all GND electric connector, and the first outer side metal pieces 51 are all Vin electric connector. The side frame of the hollowed-out printed circuit layer substrate 1 can be made as thin as possible to reduce the parasitic inductance of the VIN-GND loop (i.e., the input loop).

As shown in FIG. 2C, the outer side wall of the other part of the printed circuit layer substrate 1 is further provided with a second outer side metal piece 52 corresponding to the position of the side wall metal piece 3, the second outer side metal piece 52 is electrically connected with the corresponding side wall metal piece 3, and they are electrically connected through wiring on the upper surface of the carrier plate. Furthermore, the second outer side metal piece 52 and the first outer side metal piece 51 on the outer walls of the two sides are adjacently arranged, and the corresponding side wall metal pieces 3 are integrally and electrically connected, so that an input loop is formed on the outer side wall while an input loop is formed between the inner/outer side walls of the frame of the printed circuit board substrate 1, and the parasitic inductance of the loop can be further reduced.

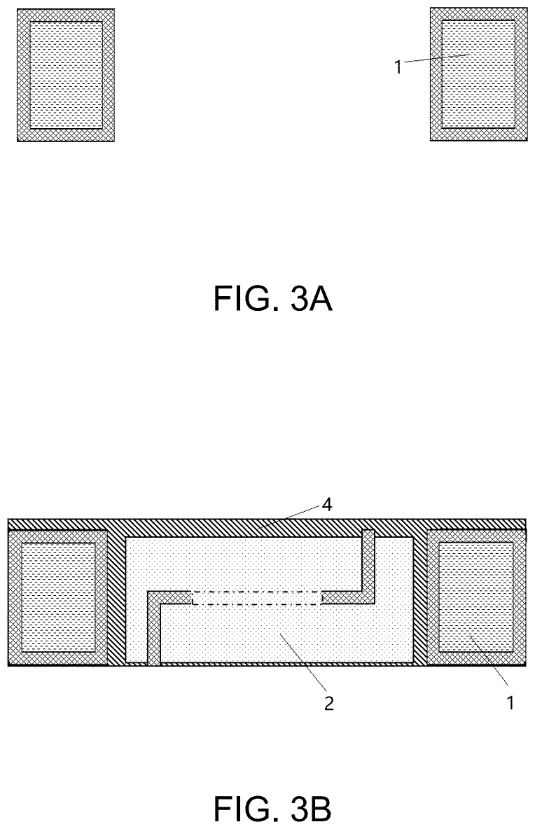

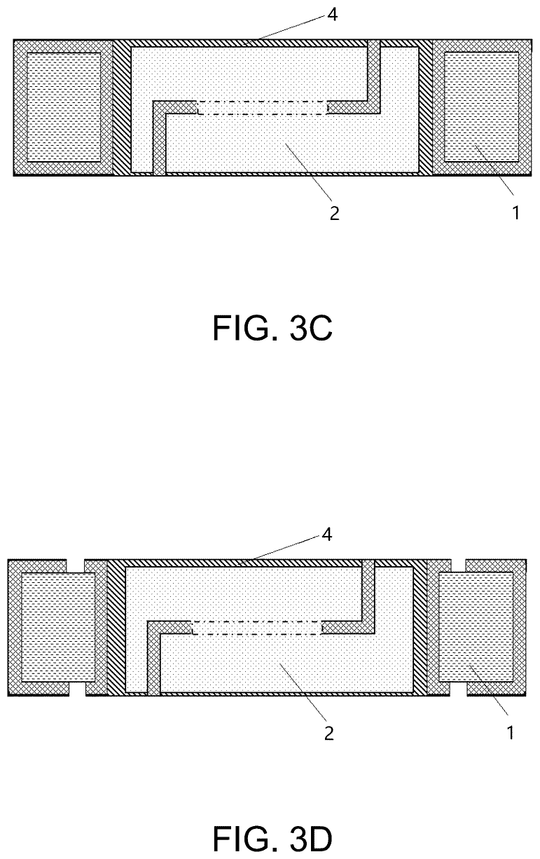

FIG. 3A to FIG. 3D show a manufacturing process of the present embodiment, comprising the following steps:

Step S1, the printed circuit layer substrate 1 is hollowed out, then copper is plated on the whole plate, and the pattern definition of the copper on the side wall of the hollowed-out area is completed, as shown in the carrier plate frame shown in FIG. 3A.

Step S2, fixedly connecting the carrier plate frame and the inductance element 2 through an insulating bonding dielectric layer 4, as shown in FIG. 3B.

Step S3, performing a planarization process, and removing the redundant bonding dielectric layer 4, as shown in FIG. 3C.

Step S4: After pattern definition, etching is performed to obtain the carrier plate as shown in FIG. 3D.

### Embodiment 2

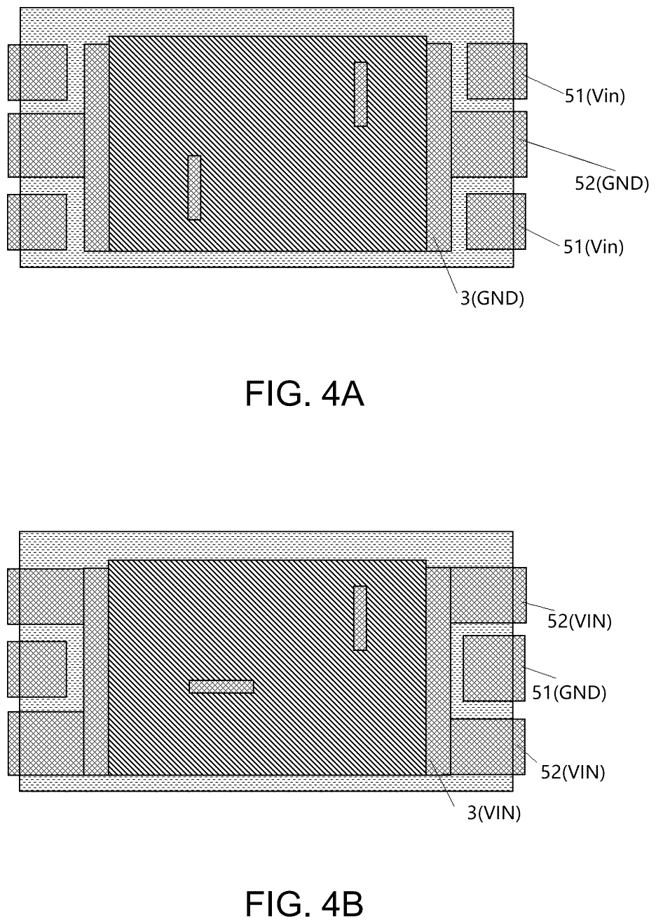

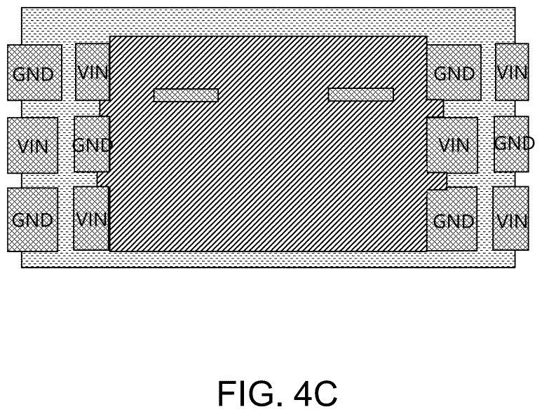

The difference between the embodiment and the first embodiment lies in that a plurality of first outer side metal pieces 51 or second outer side metal pieces 52 can be arranged on one side face, as shown in FIG. 4A and FIG. 4B. In the embodiment, the side wall metal pieces 3 are integrated on the side face of the inductance element 2, and in other embodiments, the side wall metal pieces 3 can be electrically and alternately arranged, and the corresponding second outer side metal pieces 52 are electrically connected with the adjacent first outer side metal pieces 51. The advantage of doing so is that the parasitic inductance of the loop can be further reduced. In another preferred embodiment, as shown in FIG. 4C, without the second outer side metal piece 52, the side wall metal piece 3 and the first outer side metal piece 51 can be alternately arranged on the inner/outer side wall alternately to form a plurality of input loops which are connected in parallel, and then the parasitic inductance of the loop is further reduced.

### Embodiment 3

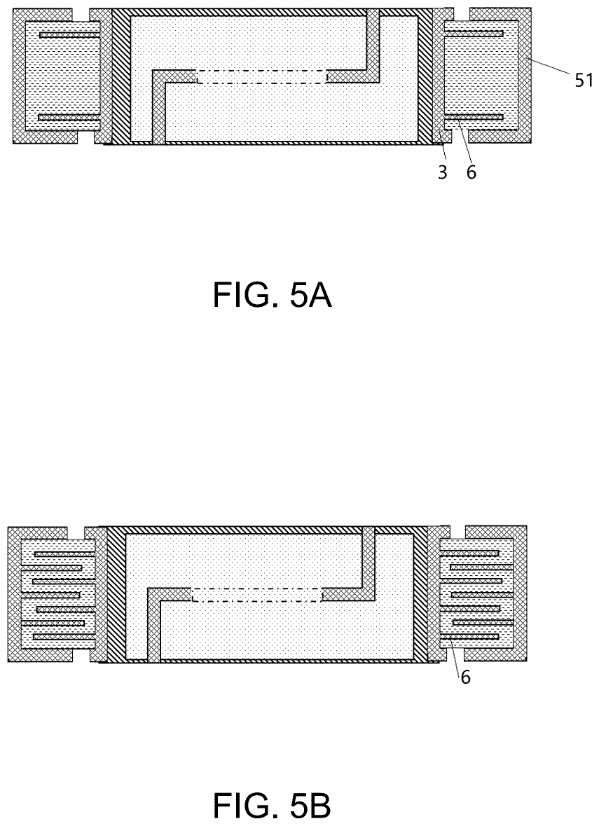

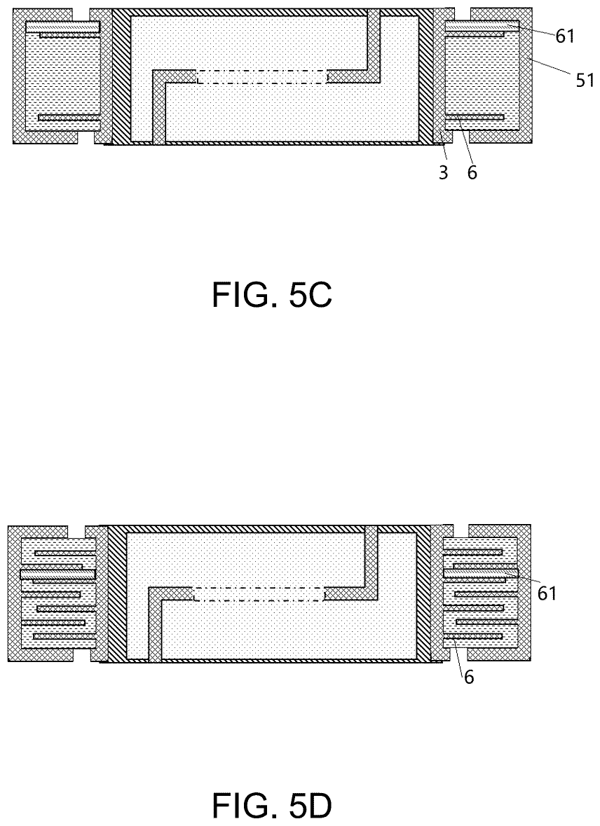

The difference between the embodiment and the first embodiment lies in that a horizontal metal layer 6 is arranged in the area between the first outer side metal piece 51 and the side wall metal piece 3 at the corresponding position of the printed circuit layer substrate 1, and each horizontal metal layer 6 is electrically connected with the first outer side metal piece 51 or the side wall metal piece 3 at the corresponding position. As shown in FIG. 5A, due to the fact that the interlayer spacing of the printed circuit layer substrate 1 is smaller than the width of the hollowed-out frame, the area of the equivalent input loop can be smaller, so that the parasitic inductance of the loop is further reduced.

In a preferred embodiment, as shown in FIG. 5B, a plurality of horizontal metal layers 6 may be provided and are alternately electrically connected to the side wall metal pieces 3 or the first outer side metal pieces 51, i.e., equivalent to forming a plurality of input loops connected in parallel.

In a preferred embodiment, as shown in FIG. 5C and FIG. 5D, a high-k insulating dielectric layer 61, such as a thin film of a high-k dielectric medium, is further provided above or below the at least one horizontal metal layer 6 to further reduce the loop inductance. Preferably, the high-k insulating dielectric layer 61 can be completely arranged in each interval region shown in FIGS. 5C and 5D.

### Embodiment 4

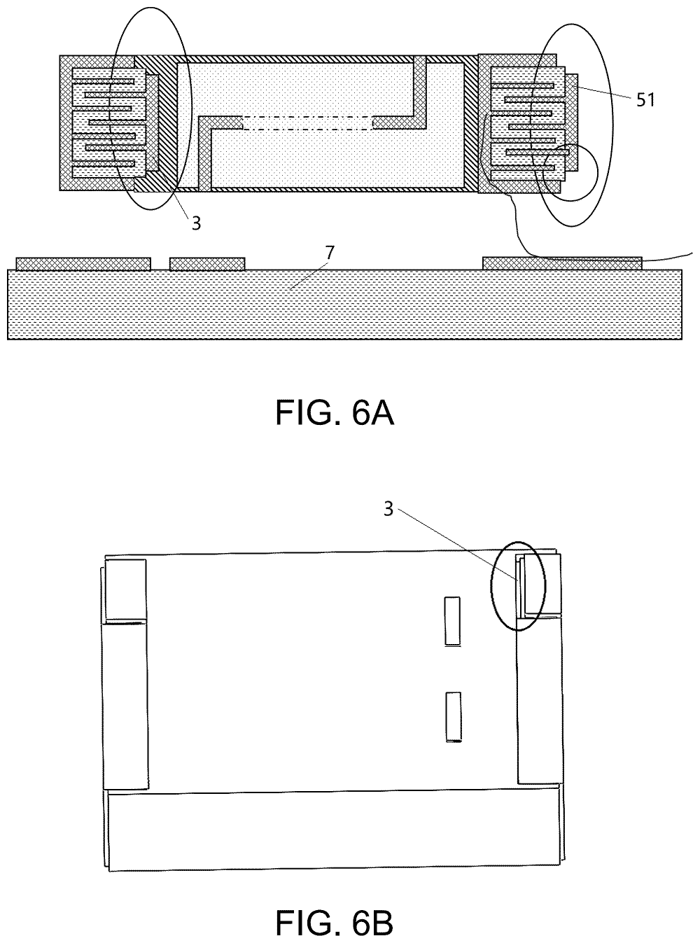

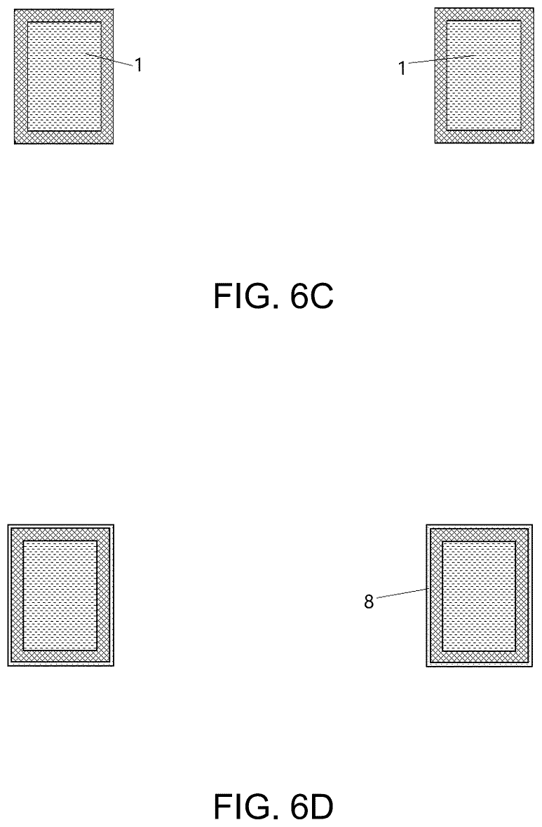

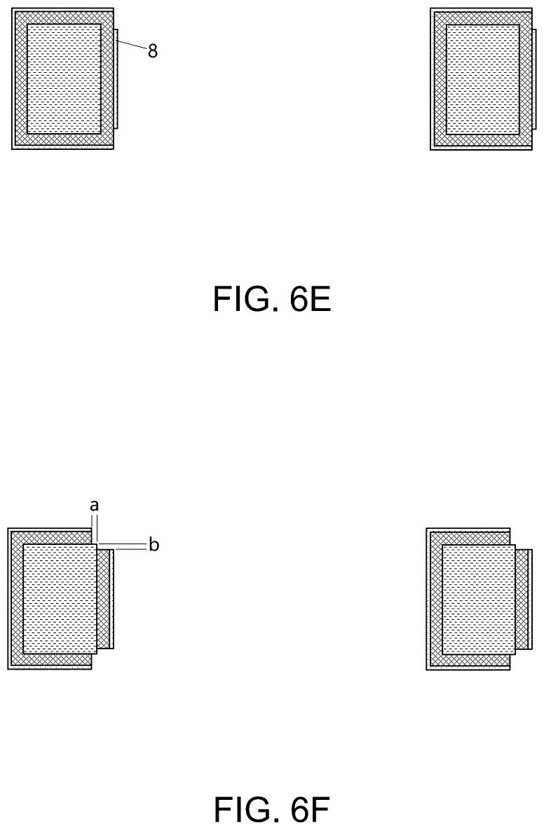

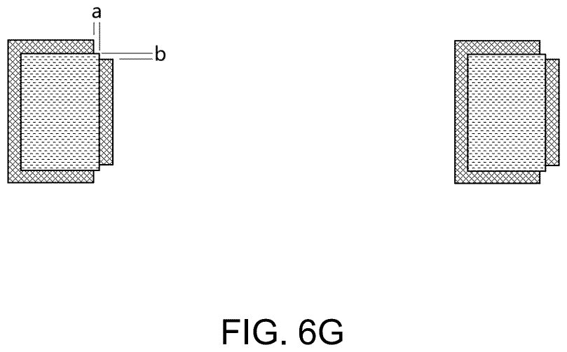

The difference between the embodiment and the first embodiment lies in that as shown in FIG. 6A and FIG. 6B (FIG. 6A perspective view), the side wall metal part 3 of the left side frame does not extend to the upper/lower surface of the carrier plate in the thickness direction of the carrier plate (the left elliptical area in FIG. 6A and the elliptical area on the right side of FIG. 6B, that is, the side wall metal part 3 is lower than the bonding dielectric layer 4), so that the size of the carrier plate can be further reduced. Similarly, the first outer side metal part 51 can also not extend to the upper/lower surface of the carrier plate along the thickness direction of the carrier plate (i.e., the first outer side metal part 51 is lower than the carrier plate edge), so that the wiring difficulty of the external mainboard 7 can be further reduced while the size of the carrier plate is further reduced (i.e., the bonding pad on the external mainboard 7 at the corresponding position does not need to avoid the position of the side wall metal part 3/the first outer side metal piece 51 which does not extend to the surface), the wiring efficiency is improved, and the wiring impedance and the like are reduced. Similarly, in the embodiments of FIG. 4A, FIG. 4B and FIG. 4C, VIN/GND and the like are arranged in a staggered manner, and the metal on the side wall of the frame/carrier plate can be set according to needs and whether the frame/carrier plate side wall metal extends to the upper/lower surface of the carrier plate. Optionally, as shown in FIG. 6A, the horizontally arranged alternately stacked VIN/GND wiring layer can also determine whether to set according to actual situations.

FIG. 6C to FIG. 6G illustrate a method for manufacturing a sidewall structure of the present embodiment, comprising the following steps:
Step S1.1, hollowed out the printed circuit layer substrate 1, and then carrying out whole-plate copper plating on the printed circuit layer substrate, as shown in FIG. 6C.
Step S1.2: plating a protective layer on the entire board of the printed circuit layer substrate 1, as shown in FIG. 6D.
Step S1.3: graphic definition: removing the protective layer of the designated area, wherein the designated area comprises at least a part of the edge area, the edge area is the edge of the printed circuit layer substrate and/or the edge of the side wall formed by hollowing, and other areas needing to be etched on the surface or the side wall of the carrier plate can also be removed together in this step (the area to be etched on the surface of the carrier plate can also be etched again in a subsequent step), as shown in FIG. 6E.
Step S4, etching: removing copper in the designated area, and enabling the copper plating on the side wall of the edge area to be lower than the upper/lower surface of the printed circuit layer substrate, as shown in FIG. 6F.
Step S1.5: removing the remaining protective layer to form a carrier plate frame, as shown in FIG. 6G.
Step S2, laminating: fixedly connecting the inductance element 2 and the carrier plate frame through an insulating bonding medium layer 4.
Step S3: optionally, removing the excess bonding dielectric layer 4 by means of a planarization process.

Pattern protection is removed through the side wall, the horizontal pattern is synchronously etched, and the minimum horizontal line distance of the side wall metal piece 3/the first outer side metal piece 51/the second outer side metal piece 52 can be achieved. In a preferred embodiment, during etching, the width of the horizontal section of the etched edge area (i.e., the horizontal distance A between the copper on the upper/lower surface and the edge of the printed circuit layer substrate after etching) is less than 200 μm, the width of the vertical section (i.e., the vertical distance B between the copper of the etched side wall and the edge of the printed circuit layer substrate) is less than 200 μm, the width of the horizontal section of the edge area is less than 100 μm, the width of the vertical section of the edge area is less than 100 μm, and the space is more fully utilized while mutual insulation between the horizontal section and the vertical section copper plating can be ensured.

### Embodiment 5

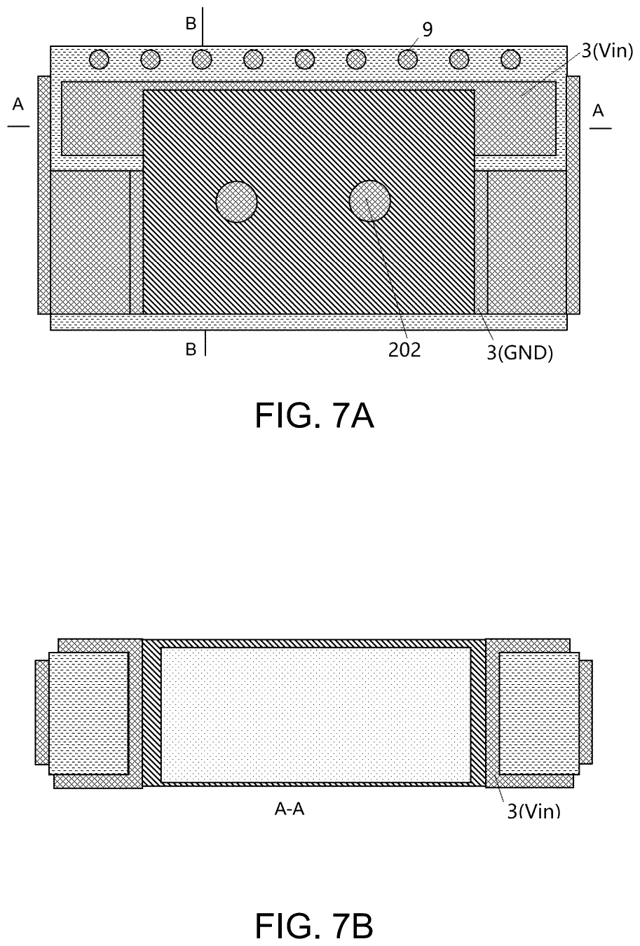

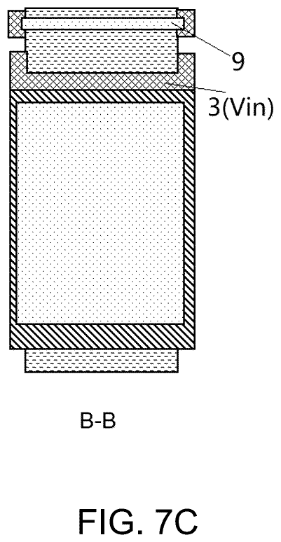

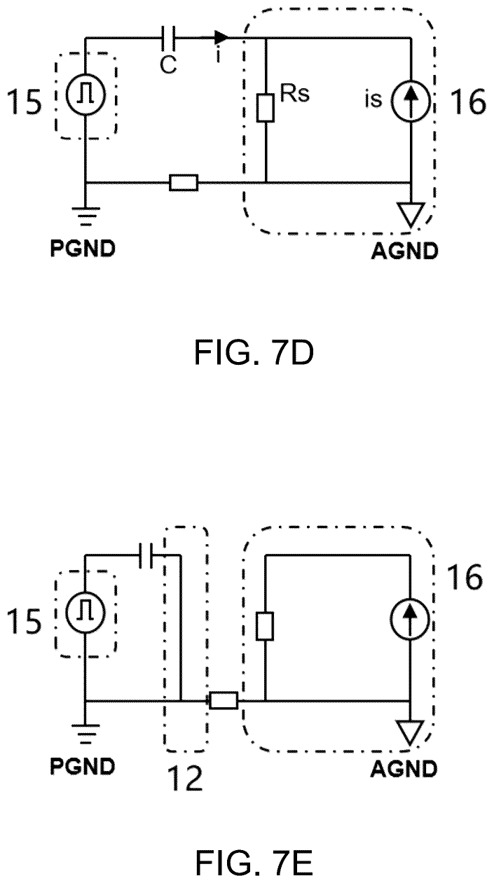

The difference between the embodiment and the first embodiment lies in that as shown in FIG. 7A to FIG. 7C, wherein FIG. 7B is an AA cross-sectional view of FIG. 7A, and FIG. 7C is a BB cross-sectional view of FIG. 7A. The carrier plate is provided with a through hole 9 for forming an electrical connection channel for connecting the first surface wiring and the second surface wiring of the carrier plate, the arrangement form of the through hole 9 can be single-row/multi-row or located on one side/multiple sides of the unit, a person skilled in the art can set according to actual needs. The through hole 9 can be used for arranging an electrical connection structure such as a signal electrical connector. In the embodiment, the side wall metal piece 3 is arranged between the through hole 9 and the winding 202, at least one part of the hollow area is provided with the side wall metal piece 3, the side wall metal piece 3 is set to be a electrostatic potential, such as Vin, GND and the like, electromagnetic interference shielding is achieved between the signal electrical connector and the winding 202 through the side wall metal piece 3, and signal interference caused by the voltage jumping of SW point on the inductor can be effectively avoided.

The principle of the signal shielding layer is shown in FIG. 7D to FIG. 7E, FIG. 7D is a common signal interference transmission path, a parasitic capacitor is arranged between the interference source 15 (such as a switch waveform) and the sampling circuit 16, and the jump signal is subjected to capacitive couple the interference current to the sampling circuit, so that the sampling signal is interfered. The side wall of the hollowed-out area is metalized, and the metal is connected to a relatively stable potential, such as a power supply or a ground wire of Vin, GND, Vout, VDD and the like, so that an interference coupling path can be cut off, and as shown in FIG. 7E, interference of an interference source 15 in the cavity to an external signal is eliminated. The side wall metal piece 3 can also shield a high-frequency loop, so that the loop inductance is reduced, and the external interference of the carrier plate system is reduced.

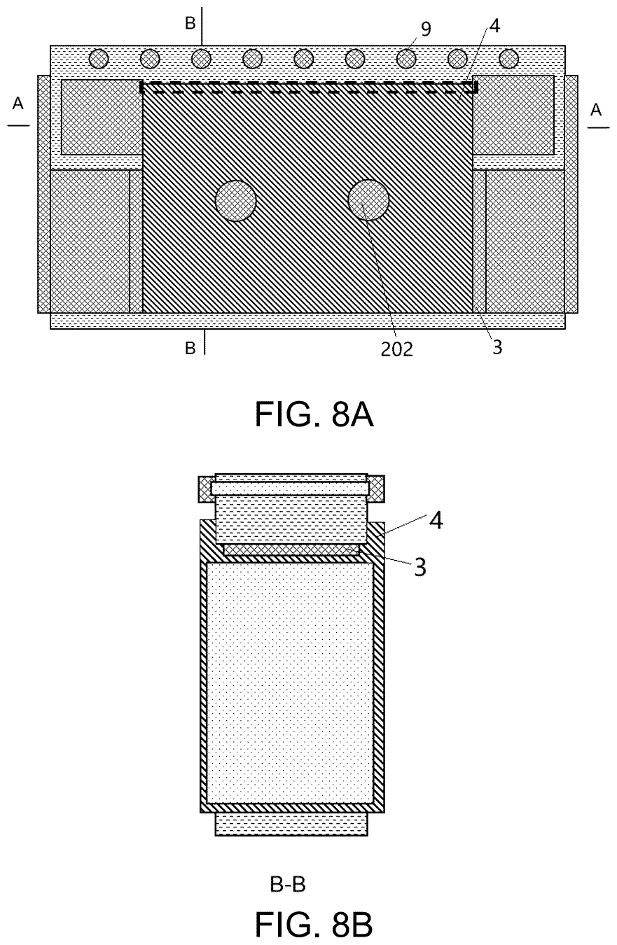

In a preferred embodiment, as shown in FIG. 8A to FIG. 8B, FIG. 8B is the BB cross-sectional view of FIG. 8A, the AA cross-sectional view of FIG. 8A is similar to that of FIG. 7B, and the side wall metal member 3 (the position shown by the dashed box in FIG. 8A and the position labeled as the sidewall metal member 3 in FIG. 8B) of the embodiment are lower than the insulating bonding medium layer 4, so as to further reduce the size of the carrier plate.

### Embodiment 6

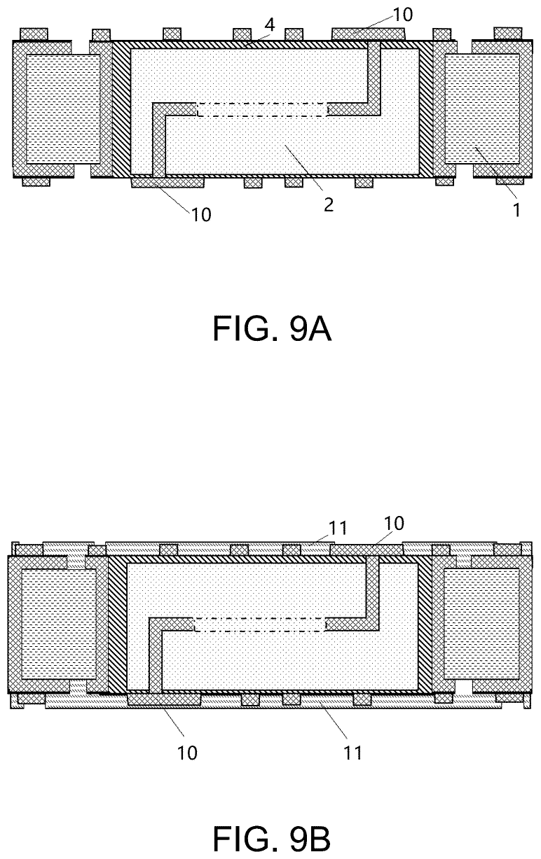

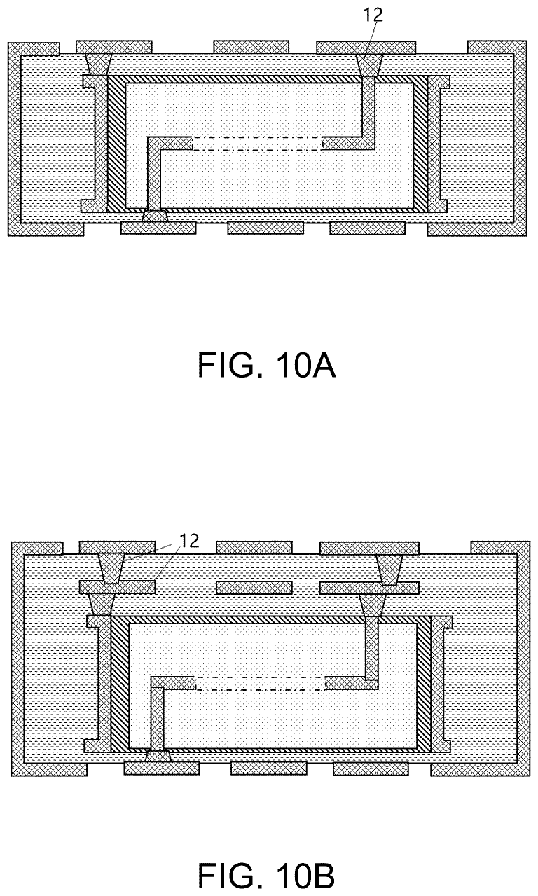

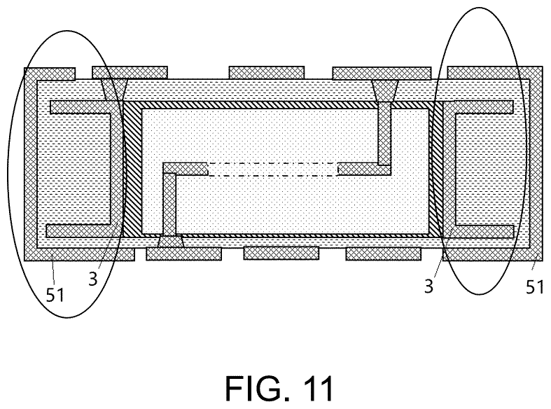

The difference between the embodiment and the first embodiment lies in that as shown in FIG. 9A, a wiring layer 10 is arranged on at least one surface of the carrier plate. In a preferred embodiment, as shown in FIG. 9B, the wiring layer comprises an insulating dielectric region 11 between wirings, so as to further increase solder resist.

In a preferred embodiment, as shown in FIG. 10A and FIG. 10B, more wiring layers 10 can be laminated on the carrier plate, and longitudinal electrical connection can be realized through the blind holes 12.

In a preferred embodiment, as shown in FIG. 11, the first outer metal piece 51 may extend to the wiring layer 10 so as to form VIN-GND overlap with the corresponding sidewall metal piece 3 in the thickness direction (the part shown in the elliptical region in FIG. 11), thereby providing a better coupling effect of the input loop.

### Embodiment 7

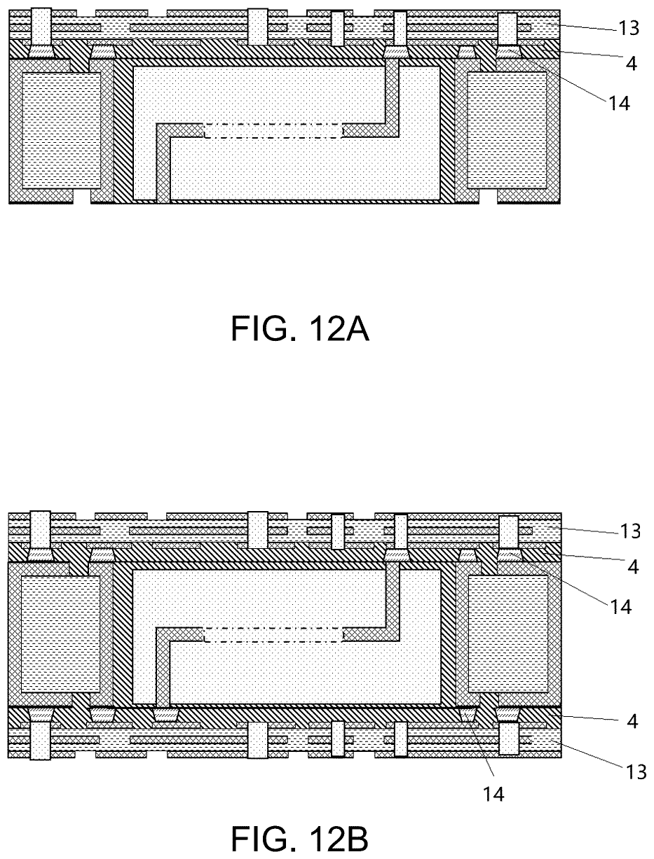

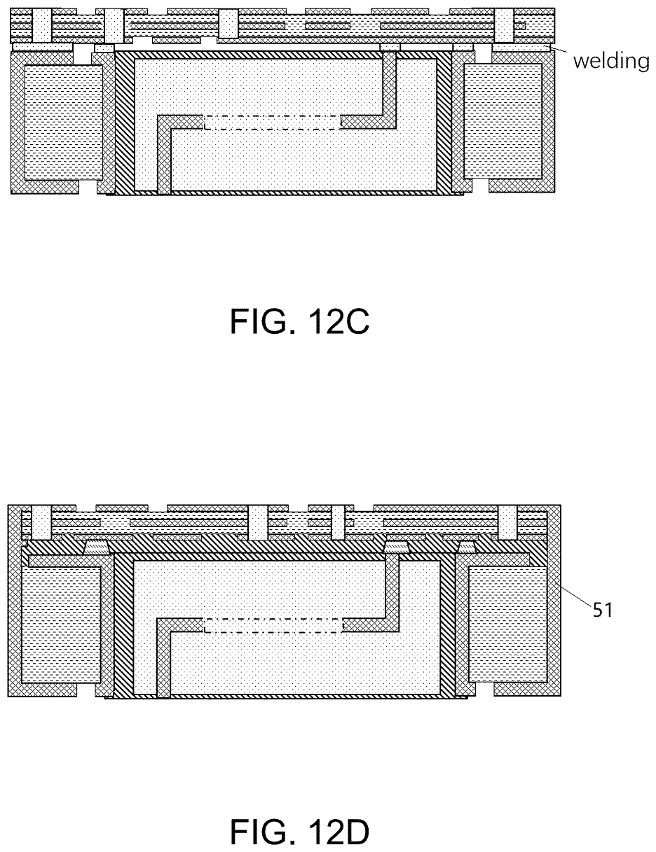

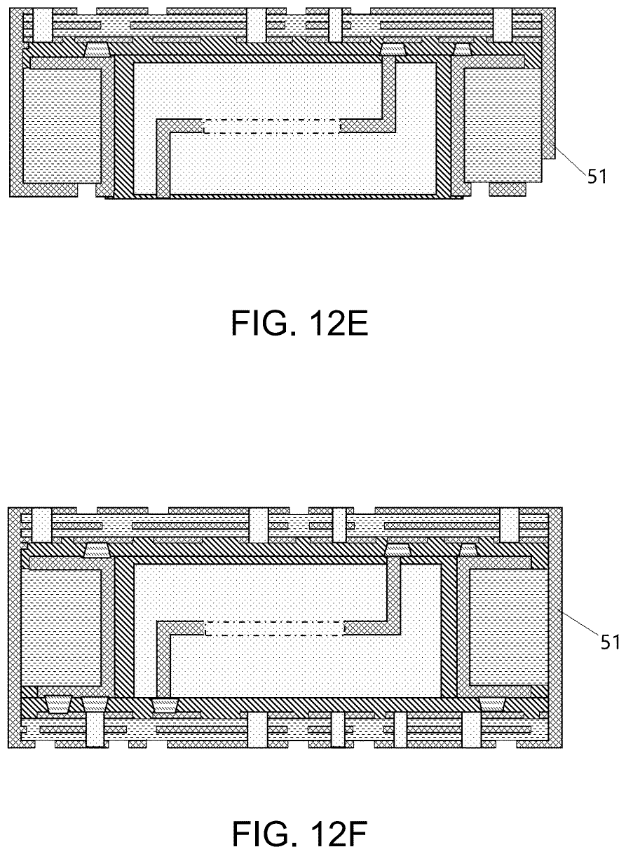

This embodiment differs from Embodiment 1 in that at least one surface of the carrier plate is provided with a printed circuit board stack layer 13, as shown in FIG. 12A and FIG. 12B, the printed circuit board stack layer 13 is fixedly connected to the carrier plate by means of an insulating bonding medium layer 4, and is electrically connected to the carrier plate by means of the bonding material piece 14. Preferably, the through hole can be formed after the lamination, and the through hole is used for fan-out of the signal connector. The bonding medium layer 4 is made of an insulating medium material such as a prepreg (Pre-Preg) or ABF (Ajinomoto Build-Up Film). The bonding material piece 14 is made of brazing filler metal, tin-silver alloy, tin-copper alloy, tin-silver-copper alloy, tin-antimony alloy, gold-tin alloy, high-lead solder, silver sintering slurry, copper sintering slurry, instantaneous liquid-phase sintering material or conductive slurry. Due to the effective constraint and protection of the insulating medium on the bonding material piece 14, the reliability of the bonding material piece 14 can be effectively improved. The manufacturing method of the embodiment is briefly described as follows:
Step S1: preparing a substrate embedded with a magnetic core and a printed circuit board stack layer 13.
Step S2, arranging a bonding medium layer 4 on the surface of a substrate or a printed circuit board stack layer 13 embedded with a magnetic core, and performing semi-curing.
Step S3: opening a window on the bonding medium layer 4.
Step S4, arranging a bonding material piece 14 at the windowing position, and baking to remove the solvent, wherein the bonding material piece 7 can be a silver sintering material, a copper sintering material, an instantaneous liquid-phase sintering material, conductive paste and the like.
Step S5: laminating the substrate embedded with the magnetic core and the printed circuit board stack layer 13.

In a preferred embodiment, as shown in FIG. 12C, the printed circuit board stack layer 13 may be fixedly connected by welding and a carrier plate.

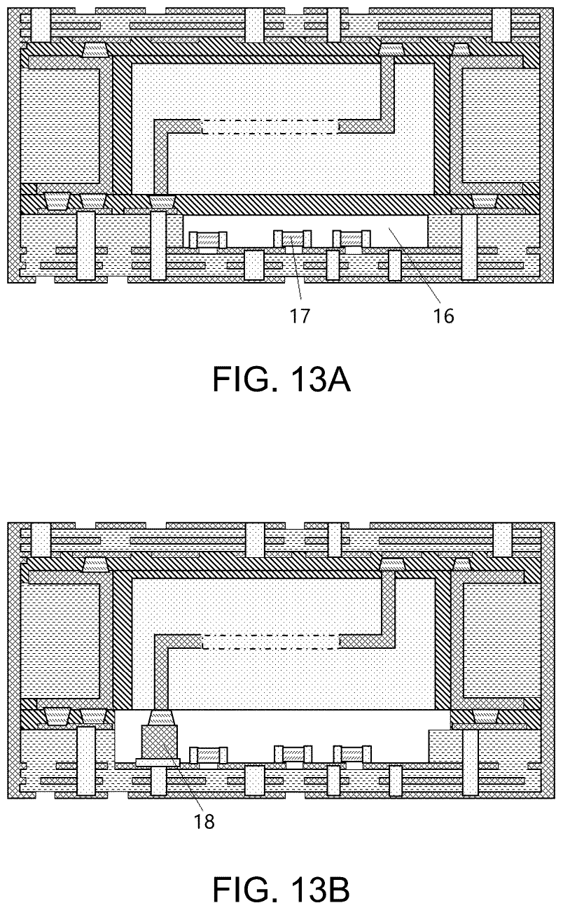

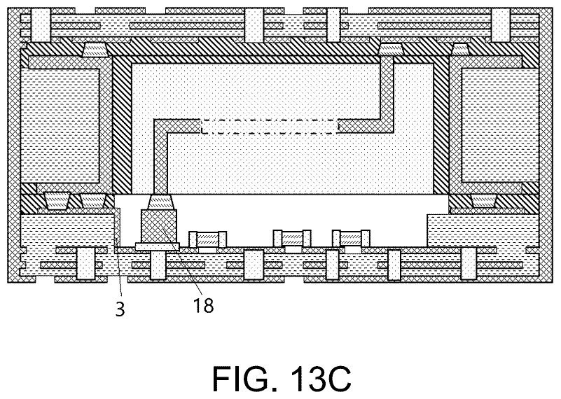

In a preferred embodiment, as shown in FIG. 12D to FIG. 12F, the printed circuit board stack layer 13 and the side wall of the carrier plate are provided with an integrated first outer side metal piece 51. In FIG. 12D and FIG. 12E, the upper surface of the carrier plate is provided with a printed circuit board stack layer 13, the fan-out forms of the metal parts on the lower surface of the carrier plate are different, and a person skilled in the art can set the metal parts according to needs. In a preferred embodiment, as shown in FIG. 13A, at least one printed circuit board stack layer 13 is provided with a laminated hollowed-out area 16, the laminated hollowed-out area 16 is used for arranging a power supply circuit assembly 17. The power supply circuit assembly 17 comprises a capacitor, and in some optimized embodiments, the opening direction of the laminated hollowed-out area 16 faces the carrier plate. In a preferred embodiment, as shown in FIG. 13B and FIG. 13C, the positions of the hollowed-out areas of the laminated hollowed-out area 16 and the printed circuit layer substrate 1 can be aligned, and the bonding medium layer 4 can be omitted on the surface of the corresponding side of the inductive element 2. The pins with large through-flow can also be achieved the external fan-out through a metal guide column 18, such as a copper column. The side wall of the laminated hollowed-out area 16 may be provided with a side wall metal piece 3 (FIG. 13C), or may not be provided (FIG. 13B).

### Embodiment 8

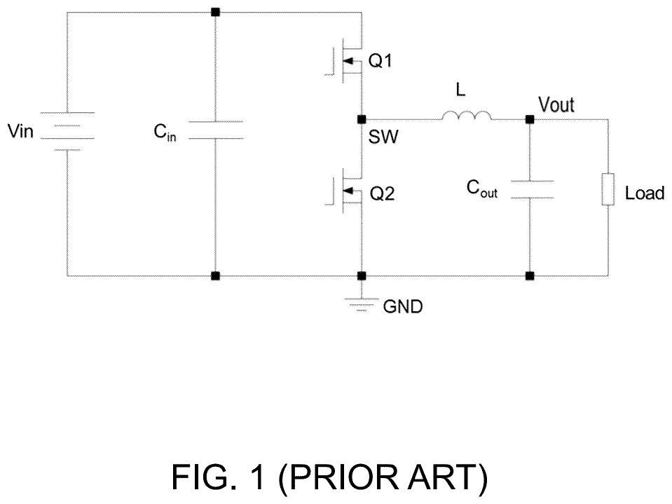

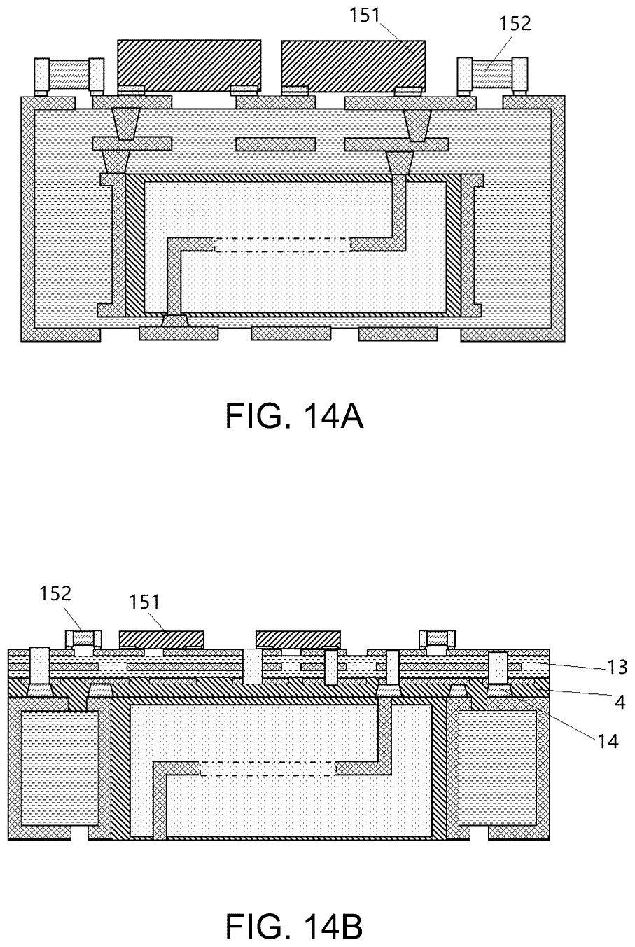

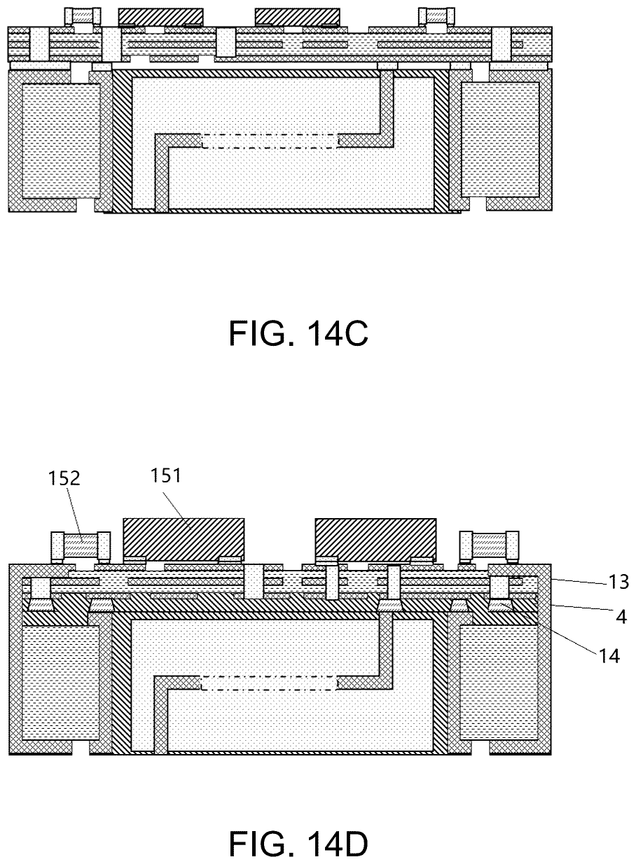

The embodiment of the application discloses an application scene of a carrier plate of the embodiment. As shown in FIG. 14A to FIG. 14D, elements such as a power device 151 and a capacitor 152 are arranged on the upper surface of the carrier plate. FIG. 14A adopts the carrier plate shown in FIG. 10B, FIG. 14B adopts the carrier plate shown in FIG. 12A, FIG. 14C adopts the carrier plate shown in FIG. 12C, and FIG. 14D adopts the carrier plate shown in FIG. 12C. After the necessary elements in the circuit shown in FIG. 1 are arranged, a corresponding BUCK circuit is formed. Due to the fact that the metal piece on the inner/outer side wall of the frame can electrically connect the input end to the power device on the upper surface, the SW end of the power device 151 provides output current to the lower surface through the winding in the magnetic core, so that the power device can be suitable for an ultra-thin vertical power supply module and other scenes. Optionally, elements mounted on the surface of the carrier plate can be protected by plastic packaging and the like.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A carrier plate configured for a power supply module, comprising at least one hollowed-out area, an inductance element is arranged in the hollowed-out area, the inductance element comprises a magnetic core and a winding penetrating through the magnetic core, a side wall metal piece is arranged on at least one part of a side wall of the hollowed-out area, the at least one side wall metal piece is configured for being electrically connected with one electrostatic potential end of the power supply module, and the inductance element is fixedly connected with the side wall of the hollowed-out area through an insulating bonding medium layer.

2. The carrier plate of claim 1, wherein a first outer side metal piece corresponding to a position of the side wall metal piece is arranged on an outer side wall of at least one part of the carrier plate, and the first outer side metal piece and the corresponding side wall metal piece are respectively configured for being electrically connected with terminals with different electrical properties of the power supply module.

3. The carrier plate of claim 2, wherein at least a part of the outer side wall of the carrier plate is provided with a second outer side metal piece corresponding to the position of the side wall metal piece, and the second outer side metal piece is electrically connected to the corresponding side wall metal piece.

4. The carrier plate of claim 3, wherein the second outer side metal piece and the at least one first outer side metal piece are arranged adjacent to each other;
the second outer side metal piece is electrically connected with the adjacent first outer side metal piece, or the side wall metal piece at a corresponding position of the second outer side metal piece is electrically connected with the side wall metal piece at a corresponding position of the adjacent first outer side metal piece.

5. The carrier plate of claim 2, wherein the side wall metal parts are arranged in an array in a horizontal direction of the carrier plate and are electrically and alternately arranged.

6. The carrier plate of claim 2, wherein a horizontal metal layer is arranged in an area between the first outer side metal piece and the side wall metal piece at a corresponding position, and each horizontal metal layer is electrically connected with the first outer side metal piece or the side wall metal piece at the corresponding position.

7. The carrier plate of claim 6, wherein a plurality of the horizontal metal layers are arranged and are alternately electrically connected with the side wall metal pieces/the first outer side metal pieces.

8. The carrier plate of claim 6, wherein an insulating dielectric layer is provided above or below the at least one horizontal metal layer.

9. The carrier plate of claim 2, at least one part of the first outer side metal piece does not extend to at least one surface of the carrier plate in a thickness direction of the carrier plate.

10. The carrier plate of claim 1, wherein at least a part of the side wall metal piece does not extend to at least one surface of the carrier plate in a thickness direction of the carrier plate.

11. The carrier plate of claim 1, further comprising a signal electrical connector, wherein the signal electrical connector is arranged in a through hole, and shielding of electromagnetic interference is achieved between the signal electrical connector and the winding through the side wall metal piece.

12. The carrier plate of claim 1, wherein at least one surface of the carrier plate is provided with a wiring layer.

13. The carrier plate of claim 12, wherein the wiring layer comprises an insulating dielectric region between wirings.

14. The carrier plate of claim 1, wherein at least one surface of the carrier plate is provided with a printed circuit board stack layer, the printed circuit board stack layer is fixedly connected with the carrier plate through an insulating bonding medium layer, and the printed circuit board stack layer is electrically connected with the carrier plate through a bonding material piece.

15. The carrier plate of claim 14, wherein a side wall of the carrier plate and a side wall of the printed circuit board stack layer are provided with an integrated outer metal piece.

16. The carrier plate of claim 14, wherein at least one of the printed circuit board stack layers is provided with a laminated hollowed-out area, the laminated hollowed-out area is configured for arranging a power supply circuit assembly, and the power supply circuit assembly comprises a capacitor.

17. A manufacturing method of the carrier plate of claim 9, the manufacturing method comprising following steps:
S1, hollowing out a printed circuit layer substrate, and then carrying out whole-plate copper plating on the printed circuit layer substrate;
S2, plating a protective layer on the whole printed circuit layer substrate;
S3, graphic definition: removing a protective layer of a designated area, wherein the designated area comprises at least a part of an edge area, and the edge area is an edge of the printed circuit layer substrate and/or a side wall edge formed by hollowing;
S4, etching: removing copper in the designated area, and enabling the side wall copper plating of the edge area to be lower than an upper surface/a lower surface of the printed circuit layer substrate;
S5: removing the remaining protective layer to form a carrier plate frame; and
S6, laminating: fixedly connecting the inductance element and the carrier plate frame through an insulating bonding dielectric layer.

18. The manufacturing method of claim 17, wherein a width of a horizontal section of the edge area is less than 200 μm, and a width of a vertical segment of the edge area is less than 200 μm.

19. The manufacturing method of claim 18, the width of the horizontal section of the edge area is smaller than 100 μm, and the width of the vertical section of the edge area is smaller than 100 μm.
